(19) United States
(12) Patent Application Publication
(10) Pub. No.: US 2003/0054677 A1
(43) Pub. Date: Mar. 20, 2003

(54) Terminal of connector

(76) Inventor: Chung-Ming Lee, Ping Jhen City (TW)

Correspondence Address: RABIN & BERDO, P.C., Suite 500, 1101 14 Street, N.W., Washington, DC, 20005, US

(21) Appl. No.: 09/951,969

(22) Filed: Sep. 14, 2001

(51) Int. Cl. H05K 1/00

(52) U.S. Cl. 439/79

(57) ABSTRACT

The present invention includes a connector with a plurality of insertion holes that each is connected with a male terminal. A plurality of serration is installed at the middle part of the male terminal for fastening the male terminal inside the insertion holes. The rear part of the male terminal is bent to form a Z-shaped leg that is connected with a connecting point on the circuit board. The device is characterized in that the Z-shaped leg and the serration of the male terminal is made by press directly and then turned 90 degrees so as to make the Z-shaped leg facing downwards and have higher strength of structure which can prevent the elastic deformation. Moreover, not only the deformation of connectors caused by assembling with male terminals can be avoided but also the terminals can be assembled into connectors quickly.

### BACKGROUND OF THE INVENTION

I. Field of the Invention

This invention relates generally to a an improved structure of terminal mounted inside connecter and, more specifically, to a terminal with Z-shaped leg and serration formed by press so as to prevent terminals from elastic deformation. Not only the terminals can be assembled into connectors quickly but also the deformation of connectors caused by assembling of male terminals can be avoided.

II. Description of the Prior Art

Heretofore, it is known that computers, notebook, PDA, mobile phones, digital cameras, computer peripherals and electrics with memory card all have connector thereof for connecting with other appliance. As shown in FIG. 6 and FIG. 7, a plastic body (a) of connector has a plurality of insertion holes (a1). Each insertion hole (a1) is arranged with a male terminal (b) therein. On two lateral sides of the middle part of the male terminal (b), there is a plurality of serration (b1) for fastening the male terminal (b) in the insertion holes (a1) of the plastic body (a) of connector. The rear part of the male terminal (b) is bent to form a Z-shaped leg (b2) that is connected with a connecting point (c1) on a circuit board (c) by surface mounting technology (SMT), as shown in FIG. 8.

However, the male terminal (b) of the prior art is formed by press out of a piece of material band (d). The serration (b1) is on both the left and right sides of the male terminal (b). When a plurality of male terminals (b) are inserted into the insertion holes (a1), the serration (b1) is hooked with the two inner lateral sides of the insertion holes (a1) of the plastic body (a) and thus have a force acted on the insertion holes (a1). The inner lateral sides of the insertion holes (a1) also have a counter force that causes the insertion holes (a1) enlarged in the horizontal direction. Since not a single but a plurality of male terminals (b) are inserted into the insertion holes (a1), the plastic body (a) is easy to be warped upward, or downward, as shown in FIG. 9. Once the plastic body (a) is distorted, the Z-shaped leg (b2) of the male terminals (b) on certain positions cannot contact with the contact point (c1) on the circuit board (c) thus causes the bad contact.

Moreover, refer to FIG. 10, the rear end of the male terminals (b) is directly bent vertically to form the Z-shaped leg (b2). The width of the Z-shaped leg (b2) is quite small so that the tensile strength of the Z-shaped leg (b2) is also weak. Thus the Z-shaped leg (b2) is easy to have elastic deformation. Therefore, as shown in FIG. 10, a line of the Z-shaped leg (b2) is not on the same plane when a line of male terminals (b) is arranged into the plastic body (a). And not all of the male terminals (b) can have good contact with the contact point (c1) on the circuit board (c), as shown in FIG. 11.

Furthermore, the insertion holes (a1) of the plastic body (a) generally are arranged in two lines—up and down. In order to make the location that the Z-shaped leg (b2) connected with the contact point (c1) crossed, the width of the Z-shaped leg (b2) need to minimize at least half of the origin size. Thus the Z-shaped leg (b2) is easy to have elastic deformation and the plastic body (a) is also having bent deformation. Both may cause the overlapping of the Z-shaped legs (b2) of the up and bottom lines, as shown in FIG. 12. Therefore, it is easy to have short circuit when the Z-shaped leg (b2) is connected with the contact point (c1) on the circuit board (c).

In addition, the model of the male terminal (b) is formed in a line from the material band (d). Then the rear part of the male terminal (b) is bent by press in order to form the Z-shaped leg (b2) after a line of the male terminal (b) is inserted into the insertion holes (a1) of the plastic body (a). Such manufacturing procedure is not only inconvenience but also increasing the cost.

In order to prevent the plastic body (a) from being deformed by the insertion of the male terminal (b′) and the bad contact between the Z-shaped leg (b2) and the circuit board (c) caused by the elastic deformation of the Z-shaped leg (b2), some male terminals (b′) with serration (b3) and the Z-shaped legs (b4) are made at the same time by press in two-dimension way. The section is on the left and right sides of the male terminal (b′), as shown in FIG. 13. Afterwards, the male terminal (b′) is separated from the material band (d) and turned in certain degrees for being inserted into the insertion holes (a1). Refer to FIG. 14, the sections are turned to upwards and downwards so that the serration (b3) is also on the top and bottom side of the male terminal (b′). Thus the force in horizontal direction raised by the insertion of the male terminal (b′) into the insertion hole (a1) is eliminated. Therefore, the plastic body (a) won't be distorted. By the way, the Z-shaped legs (b4) is produced by press in order to avoid the elastic deformation.

However, the male terminal (b′) formed in two-dimention way need to be separated from the material band (d) first and then inserted into the insertion hole (a1) of the plastic body (a). To the manufacturers, such assembling procedure is not only inconvenience but also increases the manufacturing cost.

In addition, the top and bottom sides of the section of the connecting end (b5) of the male terminal (b′) are arced, as shown in FIG. 14 & 15. When the male terminal (b′) is connected with the insertion hole (a1), the male terminal (b′) is turned 90 degrees so that the arced sides of the connecting end (b5) are on the right and left sides. When the connecting end (b5) is connected with the female terminal (e), any deviation by assembling may cause the bad contact that reduces the quality of end products.

### SUMMARY OF THE INVENTION

It is therefore a primary object of the invention to provide an improved structure of terminals that are produced by press and then the rear end of the terminals are bent upwards to form Z-shaped legs. The Z-shaped legs face downward and have higher strength of structure which can prevent the elastic deformation.

A further object of the present invention is to provide a male terminal with serration that is formed directly by press and then turned to the top and bottom sides in the middle part thereof. Thus the serration is hooked with the insertion hole on the top and bottom side of the terminal so as to prevent the distortion of the plastic body of the connector caused by the assembling of the male terminal.

Another object of the present invention is to provide a male terminal that is inserted into the insertion hole of the plastic body of the connector first and then is cut at the connecting portion on the rear end of the terminal for being removed from the material band. Therefore, a plurality of male terminals can be inserted into the insertion hole of the connector fast and conveniently.

### BRIEF DESCRIPTION OF THE DRAWINGS

The accomplishment of the above-mentioned object of the present invention will become apparent from the following description and its accompanying drawings which disclose illustrative an embodiment of the present invention, and are as follows:

FIG. 1 is a perspective view of the present invention;

FIG. 2 is an explosive view of a male terminal of the present invention being assembled with a plastic body of a connector in accordance with the present invention;

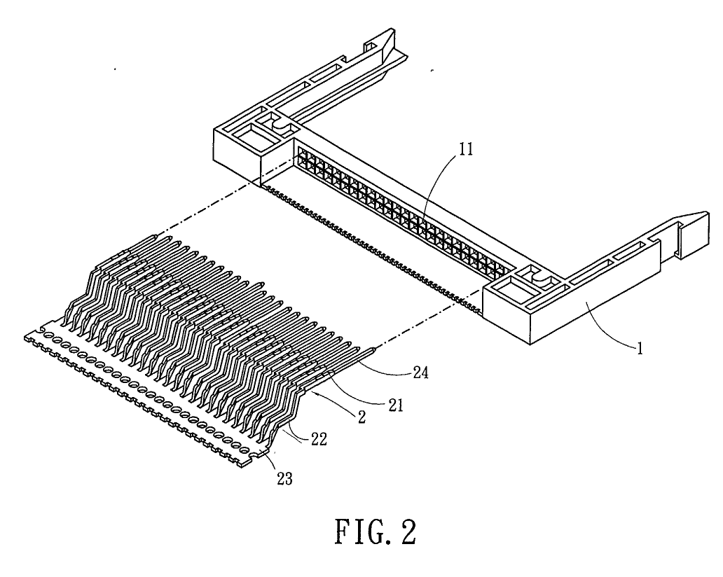

FIG. 3 is a top view of the present invention;

FIG. 4 is a cross-section view of the present invention;

FIG. 5 is a schematic diagram of the present invention when male and female terminals connect to each other;

FIG. 6 is an explosive view of a male connector of the prior art being assembled with a plastic body of a connector;

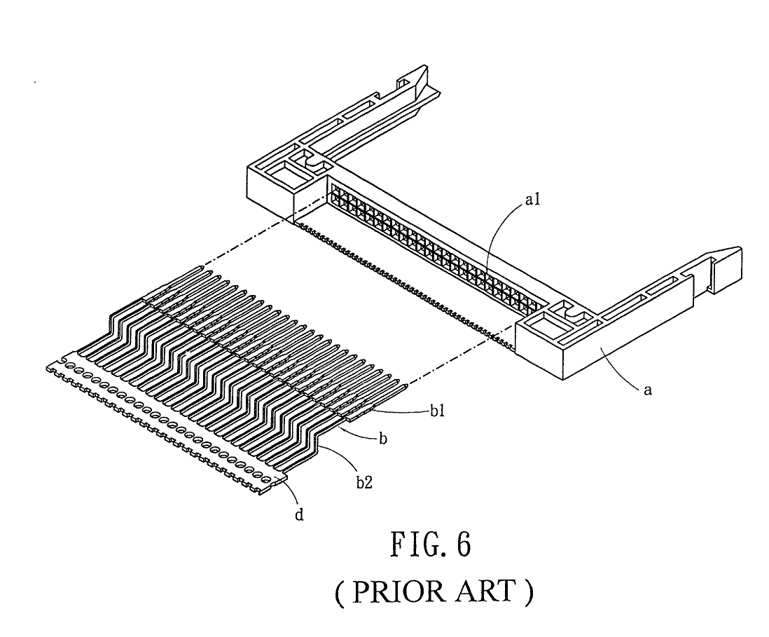

FIG. 7 is a top explosive view of the prior art;

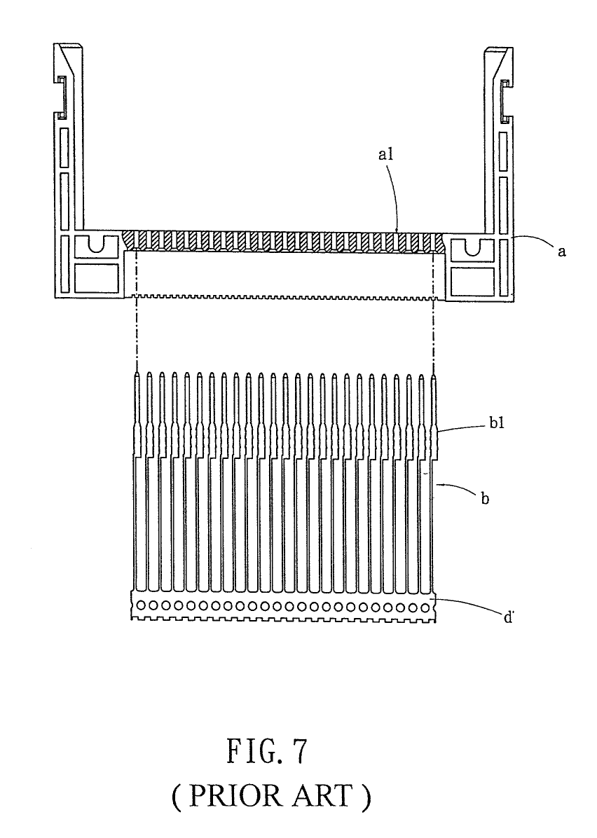

FIG. 8 is a top view of the prior art;

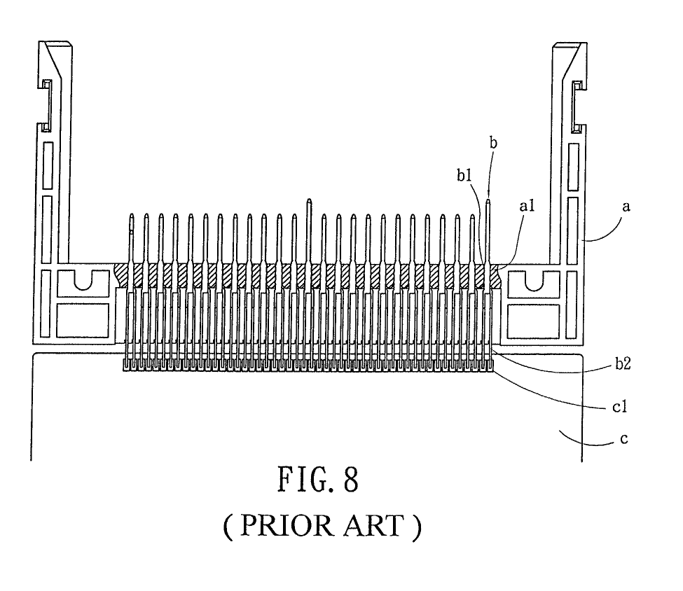

FIG. 9 is a schematic diagram of the prior art when a male terminal is assembled with a plastic body of connector and made the deformation of the plastic body;

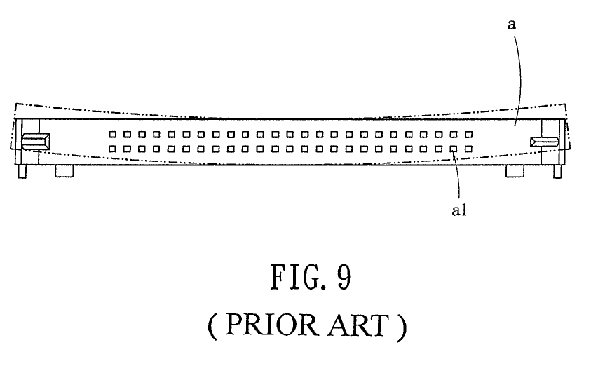

FIG. 10 is a schematic diagram of a male terminal of the prior art showing the distortion of a Z-shaped leg on the rear end thereof.

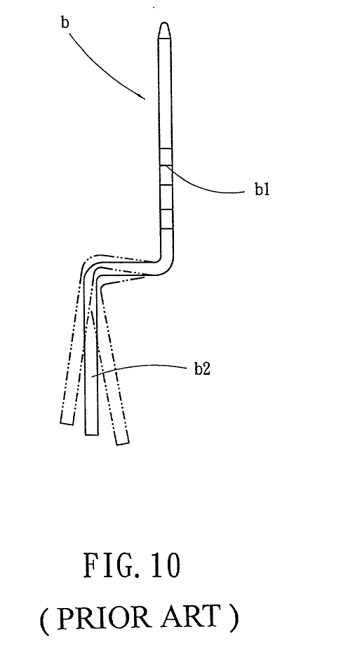

FIG. 11 is a schematic diagram of two lines of male terminals, illustrating the position error.

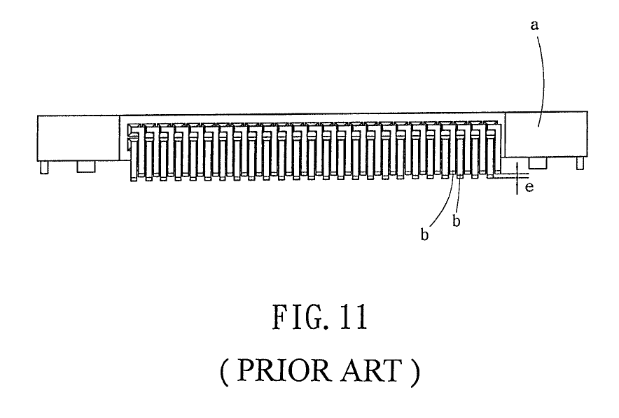

FIG. 12 is a schematic diagram of the top view of the deviation of the male terminals.

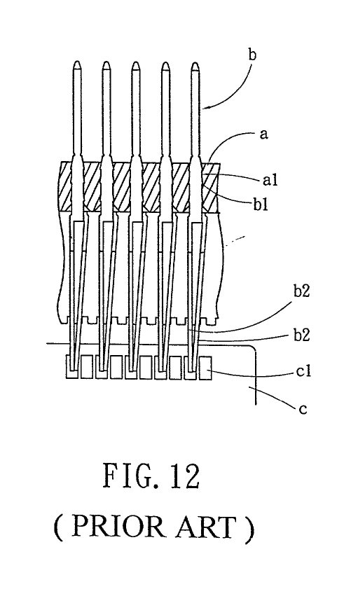

FIG. 13 is a top view of a male terminal of another embodiment of the prior art;

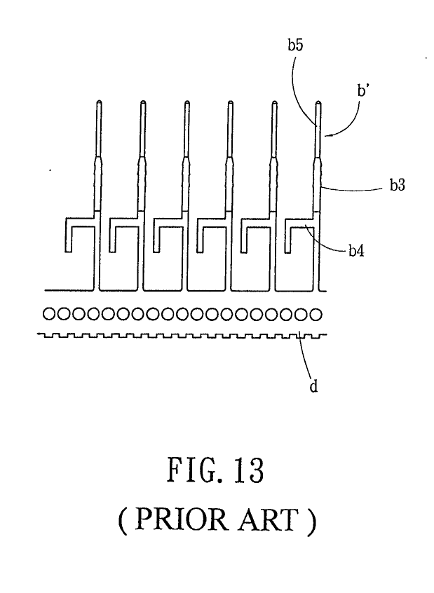

FIG. 14 is an explosive view of another embodiment of the prior art;

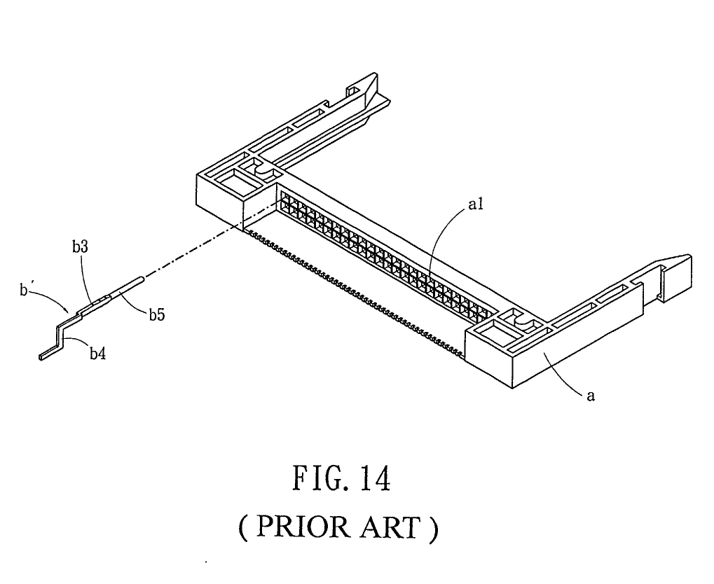

FIG. 15 is a schematic section view of the prior art, illustrating the assembling of a male terminal and a female terminal.

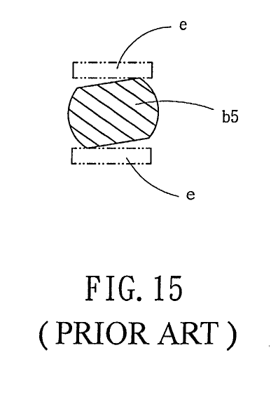

### DESCRIPTION OF THE PREFERRED EMBODIMENT

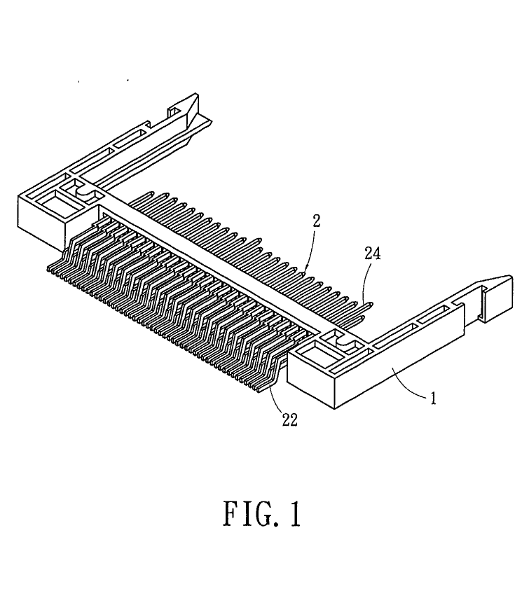

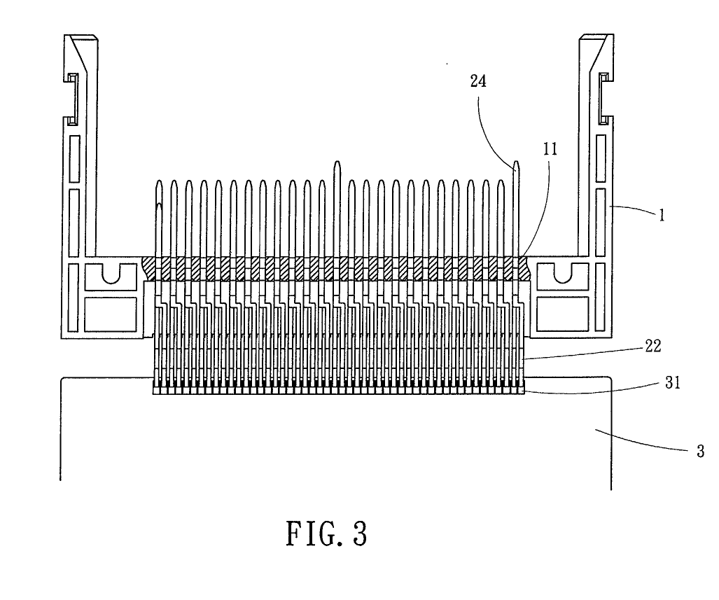

Refer to the FIGS. 1 & 2, the present invention includes a plastic body of connector 1 with a plurality of insertion holes 11, each of which accommodates a male terminal 2. A plurality of serration 21 is arranged on the middle part of the male terminal 2 for fastening the male terminal 2 inside the insertion holes 11 of the plastic body 1 of the connector. The rear part of the male terminal 2 is bent downwards to form a Z-shaped leg 22 that is connected to the connecting point 31 on the circuit board 3 by surface mounting technology (SMT), as shown in FIG. 3. The device is characterized in that:

the Z-shaped leg 22 and the serration 21 of the male terminal 2 is made by press first and then being turned 90 degrees to the desired position so that the Z-shaped leg 22 faces downwards and has higher strength of structure to avoid the elastic deformation.

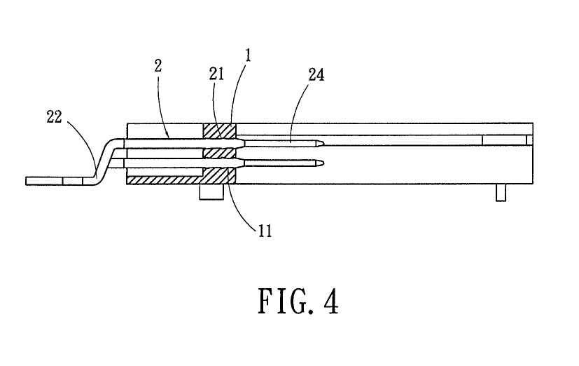

Refer to FIG. 4, a plurality of serration 21 is located on the top and bottom side of the middle part of the male terminal 2. The serration 21 is embedded inside the insertion hole 11 of the plastic body 1 of the connector on the top and bottom sides thereof. Thus the bent deformation of the plastic body 1 caused by the insertion of the male terminal 2 can be prevented.

A plurality of the male terminal 2 is inserted into the insertion hole 11 of the plastic body 1 at the same time, and then removed by the cut of connecting portion 23. Thus the male terminal 2 can be assembled with the plastic body 1 fast.

In accordance with the structure mentioned above, due to that the wider side of the Z-shaped leg 22 faces upwards and downwards, the Z-shaped leg 22 has higher strength thus can be precisely connected with the connecting point 3 on the circuit board 3 by surface mounting technology (SMT) so as to prevent the bad contact.

Furthermore, the serration 21 of the male terminal 2 is also made by press and then turned towards up and down sides. After the male terminal 2 being inserted into the insertion hole 11 of the plastic body 1, the counter force of the insertion hole 11 is in vertic direction. Thus the bent deformation of the plastic body 1 of connector caused by the insertion of the male terminal 2 can be avoided. Therefore, all of the Z-shaped legs 22 on the rear end of the male terminals 2 are located on the same plane so as to be precisely connected with the connecting point 31 on the circuit board and the bad contact is avoided.

A plurality of the male terminal 2 is inserted into the insertion hole respectively simultaneously, and then separated from the connecting portion 23 by the cut of the rear part of the Z-shaped legs 22. In such way, the inconvenient assembling of the prior art can be avoided. The manufacturing cost is down and the competitiveness on market is increased.

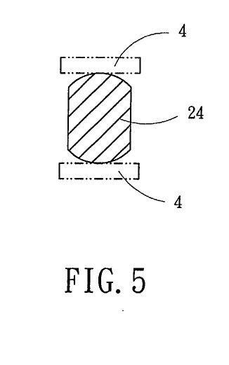

With reference of FIG. 5, the top and bottom end of the section of the insertion end 24 on the front end of the male terminal 2 are arced so that even there is some deviation when the insertion end 24 of the male terminal 2 is inserted into the female terminal 4, they still can contact well. The quality of the end product is better than prior art.

While a preferred embodiment of the invention has been shown and described in detail, it will be readily understood and appreciated that numerous omissions, changes and additions may be made without departing from the spirit and scope of the invention.

What is claimed is:

1. A terminal of connector comprising a plastic body of connector,
a plurality of insertion holes arranged at said plastic body,
a male terminal inserted inside each of said insertion hole,
a plurality of serration arranged on middle part of said male terminal for fastening said male terminal inside said insertion holes,
the rear part of said male terminal is bent downwards to form a Z-shaped leg that is connected to a connecting point on a circuit board by surface mounting technology (SMT);
The device is characterized in that:
said Z-shaped leg and said serration of said male terminal is made by press directly and then turned 90 degrees so as to make said Z-shaped leg facing downwards and have higher strength of structure which can prevent the elastic deformation; said serration is embedded inside said insertion hole of said plastic body of connector on top and bottom sides thereof thus the bent deformation of said plastic body caused by the insertion of said male terminal can be prevented; each of said male terminal is inserted into said insertion hole of said plastic body at the same time, and then removed by the cut of connecting portion on the rear side of said male terminal so as to assemble said male terminal with said insertion hole of said plastic body fast.

2. The terminal of connector as claimed in claim 1, wherein the top and bottom end of the section of an insertion end on the front end of said male terminal are arced.
